(19) United States
(12) Patent Application Publication
(10) Pub. No.: US 2019/0296050 A1
(43) Pub. Date: Sep. 26, 2019

(54) ACTIVE MATRIX SUBSTRATE AND METHOD FOR MANUFACTURING SAME

(71) Applicant: Sharp Kabushiki Kaisha, Sakai City (JP)

(72) Inventor: Keisuke YOSHIDA, Sakai City (JP)

(21) Appl. No.: 16/357,362

(22) Filed: Mar. 19, 2019

(30) Foreign Application Priority Data
Mar. 23, 2018 (JP) 2018-056104

(51) Int. Cl. H01L 27/12; H01L 29/786; H01L 29/417

(52) U.S. Cl. CPC H01L 27/124; H01L 27/1225; H01L 29/7869; H01L 27/1259; H01L 29/41733; H01L 29/78696; H01L 29/78675

(57) ABSTRACT

Each pixel of an active matrix substrate includes a TFT, the TFT including: a semiconductor layer; a gate electrode arranged on the semiconductor layer with a gate insulating layer interposed therebetween; a lower insulating layer covering the gate electrode and the semiconductor layer; and a source electrode and a drain electrode arranged on the lower insulating layer and in contact with the semiconductor layer in a source opening and a drain opening, respectively, of the lower insulating layer, wherein: the drain electrode includes a first portion in contact with only a portion of an exposed portion of the semiconductor layer that is exposed through the drain opening, a second portion located on a side surface of the drain opening, and a third portion located on an upper surface of the lower insulating layer; an upper insulating layer covering the TFT has an upper opening that partially overlaps with the drain opening; as seen from the direction normal to the substrate 1, the upper opening and the drain opening are located inside the semiconductor layer, and the drain electrode overlaps with only a portion of the drain opening and only a portion of the upper opening; and in a contact hole that includes the upper opening and the drain opening, the pixel electrode is in direct contact with at least the first portion and the second portion of the drain electrode and another portion of the exposed portion of the semiconductor layer.

### BACKGROUND

### 1. Technical Field

The present invention relates to an active matrix substrate and a method for manufacturing the same.

### 2. Description of the Related Art

An active matrix substrate used in a liquid crystal display device, or the like, includes, as a switching element, a thin film transistor (hereinafter “TFT”) for each pixel. Conventionally, as such TFTs (hereinafter, “pixel TFTs”), TFTs using an amorphous silicon film as the active layer (hereinafter, “amorphous silicon TFTs”) and TFTs using a polycrystalline silicon film as the active layer (hereinafter, “polycrystalline silicon TFTs”) have been widely used.

An oxide semiconductor is used in some cases, instead of an amorphous silicon or a polycrystalline silicon, as the material of the active layer of a TFT. Such a TFT is referred to as an “oxide semiconductor TFT”. An oxide semiconductor has a higher mobility than an amorphous silicon. Therefore, an oxide semiconductor TFT is capable of operating at a higher speed than an amorphous silicon TFT. Therefore, techniques are known in the art for monolithically (integrally) providing driving circuits such as the gate driver and the source driver on the substrate using oxide semiconductor TFTs.

Although many oxide semiconductor TFTs have a bottom gate structure, oxide semiconductor TFTs having a top gate structure are also proposed in the art (e.g., Japanese Laid-Open Patent Publication No. 2015-195363 (hereinafter, Patent Document No. 1)).

### SUMMARY

A study by the present inventor revealed that with an active matrix substrate using pixel TFTs having a top gate structure, it is difficult to reduce the size of the drain electrode. It is possible that high pixel aperture ratios have not been realized for this reason. With the inability to reduce the width of the drain electrode, it is difficult to reduce the distance between adjacent source bus lines (hereinafter, the “pixel width”), and a high definition may not be realized. The details will be described later.

An embodiment of the present invention has been made in view of the circumstances described above, and it is an object thereof to provide an active matrix substrate that includes TFTs having a top gate structure and that is capable of realizing a high pixel aperture ratio and/or a high definition.

An active matrix substrate according to one embodiment of the present invention is an active matrix substrate having a plurality of pixel regions, each pixel region including a thin film transistor supported on a substrate and a pixel electrode, wherein: the thin film transistor includes: a semiconductor layer supported on the substrate; a gate electrode arranged on the semiconductor layer with a gate insulating layer interposed therebetween; a lower insulating layer covering the gate electrode and the semiconductor layer, the lower insulating layer having a source opening and a drain opening through which a portion of the semiconductor layer is exposed; and a source electrode arranged on the lower insulating layer to be in contact with the semiconductor layer in the source opening, and a drain electrode arranged on the lower insulating layer to be in contact with the semiconductor layer in the drain opening; the drain electrode includes a first portion in contact with only a portion of an exposed portion of the semiconductor layer that is exposed through the drain opening, a second portion located on a side surface of the drain opening, and a third portion located on an upper surface of the lower insulating layer; the active matrix substrate further includes an upper insulating layer covering the thin film transistor, wherein the upper insulating layer has an upper opening that at least partially overlaps with the drain opening, and the upper opening and the drain opening together form a contact hole running through the upper insulating layer and the lower insulating layer; as seen from a direction normal to the substrate, the upper opening and the drain opening are located inside the semiconductor layer; as seen from a direction normal to the substrate, the drain electrode overlaps with only a portion of the drain opening and only a portion of the upper opening; and in the contact hole, the pixel electrode is in direct contact with at least the first portion and the second portion of the drain electrode and another portion of the exposed portion of the semiconductor layer.

In one embodiment, as seen from a direction normal to the substrate, the third portion of the drain electrode is located on a side of the gate electrode relative to the first portion.

In one embodiment, as seen from a direction normal to the substrate, the third portion of the drain electrode at least partially overlaps with the gate electrode.

In one embodiment, as seen from a direction normal to the substrate, the first width of the drain electrode along a channel width direction of the thin film transistor is smaller than a width of the upper opening along the channel width direction.

In one embodiment, on a cross section perpendicular to the substrate and extending through the drain electrode and the upper opening in the channel width direction, the drain electrode is located inside the upper opening.

In one embodiment, as seen from a direction normal to the substrate, the drain electrode includes a first end portion located on a side of the gate electrode and a second end portion located on an opposite side away from the gate electrode; and a first width of the first end of the drain electrode along a channel width direction of the thin film transistor is larger than a second width of the second end of the drain electrode along the channel width direction.

In one embodiment, as seen from a direction normal to the substrate, the first width is larger than a width of the upper opening along the channel width direction, and the second width is smaller than the width of the upper opening along the channel width direction.

In one embodiment, as seen from a direction normal to the substrate, the upper opening and the gate electrode at least partially overlap with each other; and as seen from a direction normal to the substrate, a portion of the upper opening that overlaps with the gate electrode is entirely located inside the drain electrode.

In one embodiment, the active matrix substrate includes a plurality of source bus lines extending in a column direction, and a plurality of gate bus lines extending in a row direction crossing the column direction; the source electrode is connected to a corresponding one of the plurality of source bus lines, and the gate electrode is connected to a corresponding one of the plurality of gate bus lines; and the source electrode and the drain electrode are formed from the same conductive film as the plurality of source bus lines.

In one embodiment, the active matrix substrate includes a plurality of source bus lines extending in a column direction, and a plurality of gate bus lines extending in a row direction crossing the column direction; the source electrode is connected to a corresponding one of the plurality of source bus lines, and the gate electrode is connected to a corresponding one of the plurality of gate bus lines; the source electrode and the drain electrode are formed from the same conductive film as the plurality of source bus lines; as seen from a direction normal to the substrate, a portion of the semiconductor layer that is located closer to the drain electrode than the gate electrode extends in the row direction; the drain electrode includes a first end portion located on a side of the corresponding gate bus line, and a second end portion located on an opposite side away from the corresponding gate bus line; and a first width of the first end portion of the drain electrode along the row direction is larger than a second width of the second end portion of the drain electrode along the row direction.

In one embodiment, as seen from a direction normal to the substrate, the first width is larger than a width of the upper opening along the row direction, and the second width is smaller than the width of the upper opening along the row direction.

In one embodiment, the active matrix substrate includes a plurality of source bus lines extending in a column direction, and a plurality of gate bus lines extending in a row direction crossing the column direction; the source electrode is connected to a corresponding one of the plurality of source bus lines, and the gate electrode is connected to a corresponding one of the plurality of gate bus lines; the source electrode and the drain electrode are formed from the same conductive film as the plurality of source bus lines; as seen from a direction normal to the substrate, a portion of the semiconductor layer that is located closer to the drain electrode than the gate electrode extends in the row direction; and as seen from a direction normal to the substrate, the drain electrode is arranged spaced apart from the gate electrode, and the third portion of the drain electrode at least partially overlaps with the corresponding gate bus line.

In one embodiment, the source opening is arranged so as to overlap with the corresponding source bus line; and as seen from a direction normal to the substrate, the semiconductor layer extends in an L-letter shape from the source opening to the contact hole while crossing the corresponding gate bus line.

In one embodiment, the source opening is arranged so as to overlap with the corresponding source bus line; and as seen from a direction normal to the substrate, the semiconductor layer extends in a U-letter shape from the source opening to the contact hole while twice crossing the corresponding gate bus line.

In one embodiment, the semiconductor layer is an oxide semiconductor layer.

In one embodiment, the oxide semiconductor layer includes an In—Ga—Zn—O-based semiconductor.

In one embodiment, the oxide semiconductor layer includes a crystalline portion.

In one embodiment, the semiconductor layer is a crystalline silicon semiconductor layer.

A method for manufacturing an active matrix substrate according to one embodiment of the present invention includes the steps of: forming a semiconductor layer on a substrate; forming a gate electrode on a portion of the semiconductor layer with a gate insulating layer interposed therebetween; forming a lower insulating layer so as to cover the semiconductor layer and the gate electrode, and forming a drain opening in the lower insulating layer, through which a portion of the semiconductor layer is exposed; forming a drain electrode on the lower insulating layer and in the drain opening, wherein the drain electrode is in contact with only an exposed portion of the semiconductor layer in the drain opening; forming an upper insulating layer so as to cover the lower insulating layer and the drain electrode; patterning the upper insulating layer so as to form an upper opening that at least partially overlaps with the drain opening, wherein the drain electrode and the semiconductor layer are made to function as an etch stop during the patterning; and forming a pixel electrode on the upper insulating layer, in the upper opening and in the drain opening.

According to one embodiment of the present invention, it is possible to provide an active matrix substrate that includes TFTs having a top gate structure and that is capable of realizing a high pixel aperture ratio and/or a high definition.

### BRIEF DESCRIPTION OF THE DRAWINGS

FIG. 1 is a schematic view showing an example of a planar structure of an active matrix substrate 1000.

FIG. 2A is a plan view showing a TFT 101A and a stack contact portion 20A in a pixel region Pix of the active matrix substrate 1000 of the first embodiment.

FIGS. 2B and 2C are cross-sectional views thereof taken along line A-A′ and line B-B′, respectively.

FIG. 3A is a plan view showing a TFT 101B and a stack contact portion 20B of Variation 1.

FIGS. 3B and 3C are cross-sectional views thereof taken along line A-A′ and line B-B′, respectively.

FIGS. 4A and 4B are a plan view showing a TFT 101C and a stack contact portion 20C of Variation 2, and a cross-sectional view thereof taken along line B-B′, respectively.

FIG. 5A is a plan view showing a TFT 101D and a stack contact portion 20D of Variation 3.

FIGS. 5B and 5C are cross-sectional views thereof taken along line B-C′ and line C-C′, respectively.

FIG. 6A is a plan view showing a TFT 101E and a stack contact portion 20E of Variation 4.

FIGS. 6B and 6C are cross-sectional views thereof taken along line D-D′ and line E-E′, respectively.

FIGS. 7A to 7E are step-by-step cross-sectional views illustrating an example of a method for manufacturing a TFT 101 and a stack contact portion 20.

FIGS. 8A and 8B are a plan view and a cross-sectional view, respectively, showing a TFT 101F and a stack contact portion 20F of the second embodiment.

FIG. 9 is a plan view showing a TFT 101G and a stack contact portion 20G according to a variation.

FIG. 10 is a schematic cross-sectional view illustrating a pixel width Pw.

FIG. 11 is a cross-sectional view illustrating a contact structure of a conventional active matrix substrate.

FIG. 12 is a cross-sectional view illustrating a contact structure of an active matrix substrate of Reference Example.

### DETAILED DESCRIPTION

As described above, with an active matrix substrate using pixel TFTs having a top gate structure, it is difficult in some cases to reduce the pixel width or improve the pixel aperture ratio. The reason for this will now be described.

An active matrix substrate includes a plurality of gate bus lines and a plurality of source bus lines, wherein the gate electrode of each pixel TFT is electrically connected to a corresponding one of the gate bus lines and the source electrode thereof to a corresponding one of the source bus lines. It is often the case that the gate electrode of the pixel TFT is formed from the same conductive film as the gate bus lines, and the source electrode and the drain electrode are formed from the same conductive film as the source bus line. In the present specification, a layer that is formed from the same conductive film as the gate bus lines is referred to as a “gate metal layer”, and a layer that is formed from the same conductive film as the source bus lines is referred to as a “source metal layer”.

FIG. 10 is a schematic cross-sectional view illustrating the pixel width Pw, showing a cross section including two adjacent source bus lines SL and a drain electrode DE of the pixel TFT that is located between the source bus lines SL.

As shown in FIG. 10, since the drain electrode DE and the source bus line SL of the pixel TFT are formed on the same metal layer (source metal layer), the drain electrode DE and the source bus lines SL on the opposite sides of the drain electrode DE are arranged spaced apart from each other by a certain distance w1 or more so that there is no electrical conduction therebetween. The pixel width (the distance between adjacent source bus lines) Pw is determined by the distance w1 and the width w2 of the drain electrode DE.

In order to reduce the pixel width Pw, it is preferred to reduce the width w2 of the drain electrode DE. With the pixel size being equal (the pitch, the line width, etc., of the source bus lines SL and the gate bus lines GL being equal), it is preferred that the size of the drain electrode DE is small in order to increase the pixel aperture ratio.

However, with the conventional structure as disclosed in Patent Document No. 1, it may be difficult to reduce the size of the drain electrode DE.

FIG. 11 is a cross-sectional view illustrating a pixel TFT 901 and a contact structure of a conventional active matrix substrate. This structure is disclosed in Patent Document No. 1, for example.

As illustrated in FIG. 11, the TFT 901 includes an oxide semiconductor layer 3 supported on a substrate 1, a gate electrode GE arranged on the upper side (the opposite side from the substrate) of the oxide semiconductor layer 3 with a gate insulating layer 5 interposed therebetween, and a source electrode SE and the drain electrode DE. The oxide semiconductor layer 3, the gate insulating layer 5 and the gate electrode GE are covered by a lower insulating layer 11. The source electrode SE and the drain electrode DE are formed in the source metal layer arranged on the lower insulating layer 11, and are in contact with a portion of the oxide semiconductor layer 3 through source openings 11s and 11d of the lower insulating layer 11. The pixel electrode PE is arranged on the source metal layer with an upper insulating layer 13 interposed therebetween, and is in contact with the drain electrode DE through an upper opening 13d provided in the upper insulating layer 13.

In the present specification, a contact portion 21 between the oxide semiconductor layer 3 and the source electrode SE is referred to as the “source contact portion”, a contact portion 22 between the oxide semiconductor layer 3 and the drain electrode DE as the “drain contact portion”, and a contact portion 23 between the drain electrode DE and the pixel electrode PE as the “pixel electrode contact portion”.

With the conventional contact structure shown in FIG. 11, the lower insulating layer 11 or an insulating film (a base insulating film, or the like (not shown)) on the substrate 1 side thereof may possibly be etched (overetched) when patterning the upper insulating layer 13. Thus, the drain electrode DE is normally arranged so as to overlap the entire drain opening 11d at the drain contact portion 22 and overlap the entire upper opening 13d at the pixel electrode contact portion 23, as seen from the direction normal to the substrate 1. Then, it is possible to cause the drain electrode DE to function as an etch stop when patterning the upper insulating layer 13, thereby preventing an insulating film such as the lower insulating layer 11 from being etched (overetched).

With this structure, the drain electrode DE is formed so as to extend over the drain contact portion 22 and the pixel electrode contact portion 23, thereby resulting in a large size of the drain electrode DE.

In contrast, the present inventor studied a structure (hereinafter, “stack structure”), in which the drain contact portion 22 and the pixel electrode contact portion 23 are arranged so as to overlap with each other, thereby suppressing the size of the drain electrode DE.

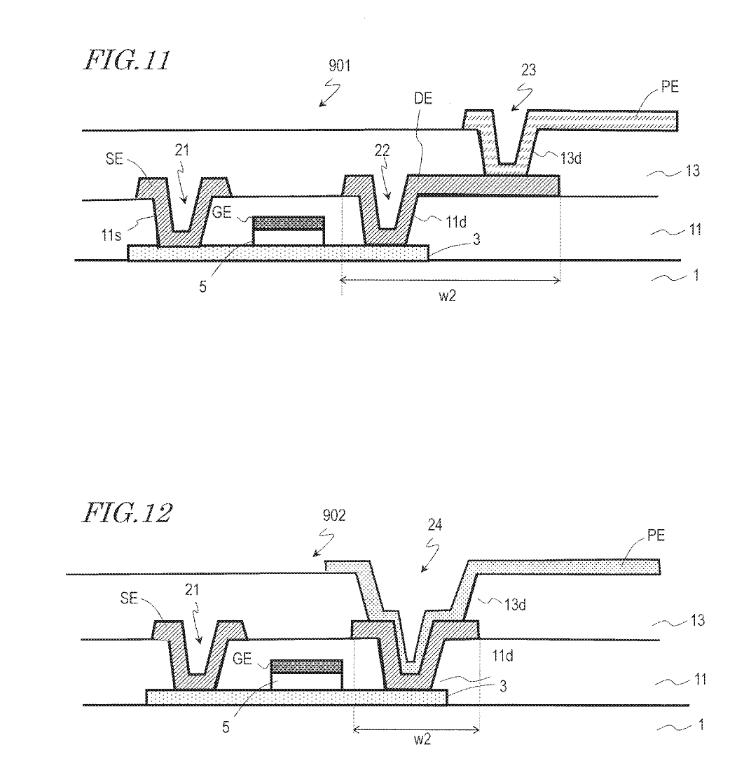

FIG. 12 is a cross-sectional view showing a pixel TFT 902 and a contact structure of an active matrix substrate of Reference Example.

With Reference Example, the drain opening 11d of the lower insulating layer 11 and the upper opening 13d of the upper insulating layer 13 are arranged so as to at least partially overlap with each other. Thus, a contact portion having a stack structure (hereinafter, a “stack contact portion”) 24 is formed.

Also in this example, the drain electrode DE is formed so as to extend over the entire stack contact portion 24, and is caused to function as an etch stop when patterning the upper insulating layer 13. Therefore, while the drain electrode DE can be made smaller than that of the conventional example shown in FIG. 11, the size depends on the size of the drain opening 11d and the upper opening 13d. Thus, there is a limit on increasing the aperture ratio and increasing the definition.

The present inventor found that it is possible to reduce the size of the drain electrode DE while suppressing the overetch of the lower insulating layer 11, the base insulating film, etc., by arranging the drain opening 11d and the upper opening 13d inside the oxide semiconductor layer 3 and arranging the drain electrode DE so as to overlap only with a portion of the drain opening 11d, as seen from the direction normal to the substrate 1.

An active matrix substrate according to an embodiment of the present invention will now be described with reference to the drawings.

### First Embodiment

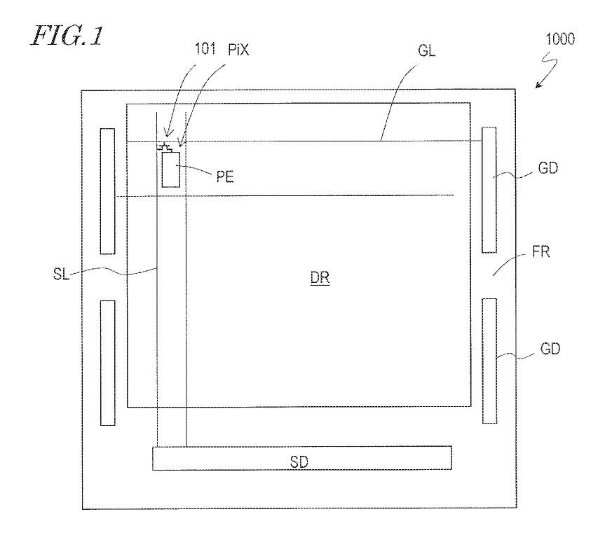

FIG. 1 is a schematic view showing an example of a planar structure of an active matrix substrate 1000 of a first embodiment.

The active matrix substrate 1000 has a display region DR, and a region (the non-display region or bezel region) FR other than the display region DR. The display region DR includes pixel regions Pix arranged in a matrix pattern. The pixel region Pix is a region corresponding to a pixel of the display device, and may be referred to simply as a “pixel”. Each pixel region Pix includes a TFT 101, which is a pixel TFT, and a pixel electrode PE. Although not shown in the figures, when the active matrix substrate 1000 is used as a display device of a transverse electric field mode such as an FFS (Fringe Field Switching) mode, a common electrode is provided on the active matrix substrate 1000 so as to oppose the pixel electrode PE with an insulating layer (dielectric layer) interposed therebetween.

The non-display region FR is a region that is located around the display region DR and does not contribute to display. The non-display region FR includes a terminal portion formation region where terminal portions are formed, a driving circuit formation region where driving circuit are provided integrally (monolithically), etc. In the driving circuit formation region, a gate driver GD, a test circuit (not shown), etc., are provided monolithically, for example. A source driver SD is mounted on the active matrix substrate 1000, for example.

A plurality of source bus lines SL extending in the column direction and a plurality of gate bus lines GL extending in the row direction crossing the column direction are formed in the display region DR. The pixels are defined by the gate bus lines GL and the source bus lines SL, for example. Each gate bus line GL is connected to a terminal of the gate driver GD. Each source bus line SL is connected to a terminal of the source driver SD mounted on the active matrix substrate 1000.

<Configuration of Pixel Region Pix>

Next, the configuration of each pixel region Pix of the active matrix substrate 1000 will be described. A TFT 101A, which is a pixel TFT, is an oxide semiconductor TFT having a top gate structure. Herein, an active matrix substrate used in a liquid crystal display panel of a VA mode will be described, as an example.

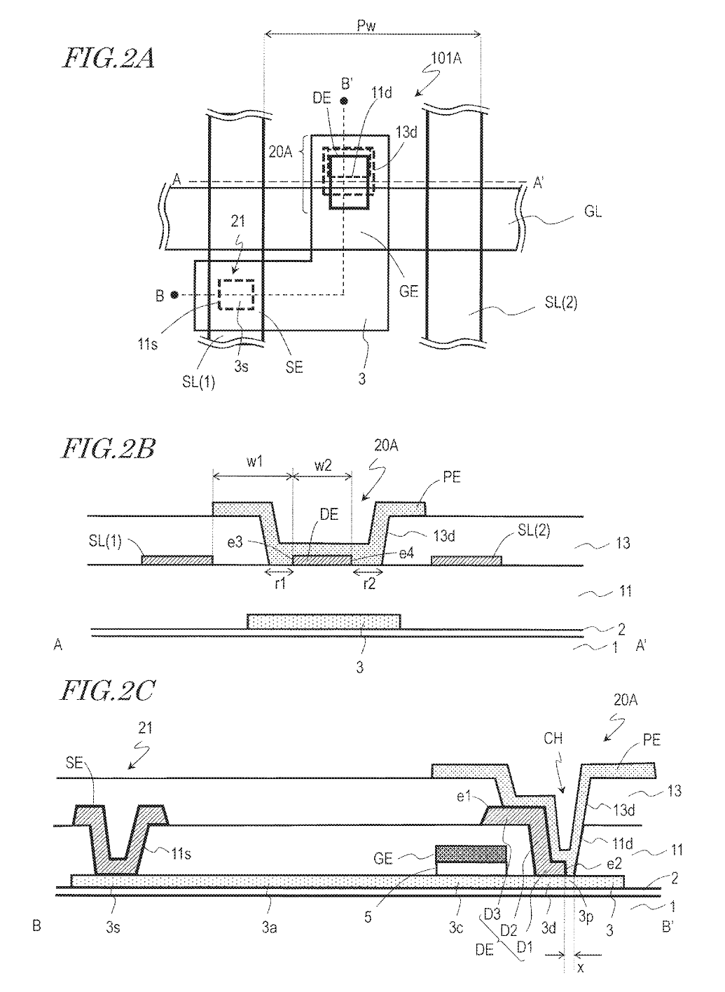

FIG. 2A is a plan view showing a portion of one pixel region Pix of the active matrix substrate 1000, showing the pixel TFT and the contact portion (stack contact portion) between the pixel TFT and the pixel electrode. FIGS. 2B and 2C are cross-sectional views taken along line A-A′ and line B-B′, respectively, of FIG. 2A.

The pixel region Pix is a region that is surrounded by two adjacent source bus lines SL (which may be referred to as source bus lines SL(1) and SL(2)) and two adjacent gate bus lines GL, for example. The pixel region Pix includes the substrate 1, the TFT (pixel TFT) 101A supported on the substrate 1, and the pixel electrode PE.

The TFT 101A includes the substrate 1, an oxide semiconductor layer (e.g., an In—Ga—Zn—O-based semiconductor layer) 3 supported on the substrate 1, the gate electrode GE, and the source electrode SE and the drain electrode DE. The gate electrode GE is arranged on a portion of the oxide semiconductor layer 3 with the gate insulating layer 5 interposed therebetween. A lower insulating layer 2 may be provided between the substrate 1 and the oxide semiconductor layer 3.

The source electrode SE and the drain electrode DE are each electrically connected to the oxide semiconductor layer 3. The source electrode SE and the drain electrode DE may be formed in the source metal layer (i.e., using the same conductive film as the source bus line SL). Similarly, the gate electrode GE may be formed in the gate metal layer (i.e., using the same conductive film as the gate bus line GL).

In this example, the gate insulating layer 5 is formed only on a region of the oxide semiconductor layer 3 that overlaps with the gate electrode GE. The gate insulating layer 5 may be in an island-like shape. The gate electrode GE and the gate insulating layer 5 may be patterned by using the same mask, for example. In such a case, the circumference of the gate electrode GE and the circumference of the gate insulating layer 5 are aligned with each other as seen from the direction normal to the substrate 1.

The oxide semiconductor layer 3, the gate insulating layer 5 and the gate electrode GE are covered by the lower insulating layer 11. The lower insulating layer 11 has the source opening 11s, through which a portion of the oxide semiconductor layer 3 is exposed, and the drain opening 11d, through which another portion of the oxide semiconductor layer 3 is exposed. Note that in FIG. 2A and the subsequent plan views, a broken line indicates the shape of the bottom surface of an opening. In the present specification, the shape and the arrangement of each opening as seen from the direction normal to the substrate 1 refer to the shape and the arrangement of the bottom surface of the opening.

The source electrode SE is arranged on the lower insulating layer 11 and in the source opening 11s, and is in contact with the exposed portion of the oxide semiconductor layer 3 in the source opening 11s. As shown in the figure, the source electrode SE may be a portion of the source bus line SL(1). The drain electrode DE is arranged on the lower insulating layer 11 and in the drain opening 11d, and is in contact with only a portion of the exposed portion of the oxide semiconductor layer 3 in the drain opening 11d. In the present specification, portions of the oxide semiconductor layer 3 that are in direct contact with the source electrode SE and the drain electrode DE are referred to as a source contact region 3s and a drain contact region 3d, respectively.

The source electrode SE covers the entire source opening 11s and the vicinity thereof. That is, the source opening 11s is located inside the source electrode SE as seen from the direction normal to the substrate 1. On the other hand, the drain electrode DE overlaps with only a portion of the drain opening 11d. The drain electrode DE may extend from a portion of the bottom surface of the drain opening 11d along a portion of the side surface of the drain opening 11d so as to cover a portion of the upper surface of the lower insulating layer 11, as shown in the figure. A portion of the drain electrode DE that is located on the bottom surface of the drain opening 11d is referred to as a first portion D1, a portion thereof that is located on the side surface of the drain opening 11d as a second portion D2, and a portion thereof that is located on the upper surface of the lower insulating layer 11 as a third portion D3. The third portion D3 may be located on the gate electrode GE side relative to the first portion D1. At least a portion of the third portion D3 may be located between the lower insulating layer 11 and the upper insulating layer 13.

The upper insulating layer 13 is formed on the lower insulating layer 11 and the source metal layer (including the source bus line SL, the source electrode SE and the drain electrode DE). The upper insulating layer 13 has the upper opening 13d. The upper opening 13d may overlap with only a portion of the drain electrode DE as seen from the direction normal to the substrate 1. A portion of the side surface of the upper opening 13d may be located on the third portion D3 of the drain electrode DE.

In the present embodiment, the upper opening 13d is arranged so as to at least partially overlap with the drain opening 11d as seen from the direction normal to the substrate 1. The upper opening 13d and the drain opening 11d form one contact hole CH extending through the upper insulating layer 13 and the lower insulating layer 11. The pixel electrode PE is arranged on the upper insulating layer 13 and in the contact hole CH, and is in direct contact with the drain electrode DE in the contact hole CH. The pixel electrode PE is in direct contact with at least a portion of the oxide semiconductor layer 3 that is exposed through the drain opening 11d and is not in contact with the drain electrode DE. A portion of the oxide semiconductor layer 3 that is in direct contact with the pixel electrode PE is referred to as a “transparent contact region 3p”.

It is preferred that the pixel electrode PE is in contact with both the first portion D1 and the second portion D2 of the drain electrode DE. Then, it is possible to more reliably ensure a contact area between the pixel electrode PE and the drain electrode DE.

As seen from the direction normal to the substrate 1, the oxide semiconductor layer 3 has a shape that is slightly larger than the contact hole CH and is arranged so as to overlap the entire contact hole CH (i.e., the drain opening 11d and the upper opening 13d). That is, the drain opening 11d and the upper opening 13d are located inside the oxide semiconductor layer 3 as seen from the direction normal to the substrate 1. Then, even when the size of the drain electrode DE is made smaller than the contact hole CH, the oxide semiconductor layer 3 can be made to function as an etch stop in a region where the drain electrode DE is absent.

As seen from the direction normal to the substrate 1, a portion of the oxide semiconductor layer 3 that overlaps with the gate electrode GE may be a channel region 3c, and a portion thereof that does not overlap with the gate electrode GE may be a low-resistance region 3a that has a lower electrical resistivity than the channel region 3c. For example, such a configuration is obtained as the resistance of a portion of the oxide semiconductor layer 3 that is not covered by the gate electrode GE with the gate insulating layer 5 interposed therebetween is lowered during the formation of the lower insulating layer 11.

According to the present embodiment, since the drain electrode DE is arranged so as to overlap only with a portion of the drain opening 11d and only a portion of the upper opening 13d, the size of the drain electrode DE can be made smaller than the conventional example and Reference Example shown in FIG. 11 and FIG. 12. Therefore, it is possible to increase the pixel aperture ratio. It is possible to suppress the overetch of the base insulating film by making the oxide semiconductor layer 3, in addition to the drain electrode DE, function as an etch stop when patterning the upper insulating layer 13.

As seen from the direction normal to the substrate 1, the area of the transparent contact region 3p may be 50% or more and 80% or less of the area of the drain opening 11d. Then, it is possible to further increase the pixel aperture ratio.

The distance x between a second end portion e2 of the drain electrode DE and the side surface of the drain opening 11d (i.e., the length of the transparent contact region 3p in the column direction) may be 50% or more and 80% or less of the length of the drain opening 11d in the column direction.

The width w2 of the drain electrode DE along the row direction may be smaller than the width of the upper opening 13d. Then, it is possible to more effectively reduce the pixel width Pw. For example, as shown in FIG. 2B, on a cross section extending through the drain electrode DE and the upper opening 13d in the row direction, a third end portion e3 of the drain electrode DE on the source bus line SL(1) side and a fourth end portion e4 thereof on the source bus line SL(2) side may each be located inside the upper opening 13d. The distance r1 between the third end portion e3 and the source bus line SL(1) and the distance r2 between the fourth end portion e4 and the source bus line SL(2) may each be 10% or more and 40% or less of the width w2 of the drain electrode DE.

Alternatively, although not shown in the figures, only one of the third end portion e3 and the fourth end portion e4 of the drain electrode DE may be located inside the upper opening 13d with the other being located outside the upper opening 13d.

As shown in FIG. 2C, on a cross section along the channel length direction of the TFT 101A, a first end portion e1 of the drain electrode DE on the gate electrode GE side (or the gate bus line GL side) may be located on the lower insulating layer 11, and the second end portion e2 thereof on the opposite side away from the gate electrode GE (or the gate bus line GL side) may be located on the bottom surface of the drain opening 11d. In this case, in the patterning step for forming the upper opening 13d in the upper insulating layer 13, the drain electrode DE may function as an etch stop on the gate electrode GE side (i.e., a region in the vicinity of the gate electrode GE) and the oxide semiconductor layer 3 may function as an etch stop on the opposite side away from the gate electrode GE (i.e., a region sufficiently away from the gate electrode GE). Then, in the step of patterning the upper insulating layer 13, a portion of the lower insulating layer 11 that is located in the vicinity of the gate electrode GE is etched, thereby exposing the gate electrode GE or the gate bus line GL and suppressing occurrence of a gate-drain leak. On the other hand, in a region sufficiently away from the gate electrode GE, since the drain electrode DE is absent, the lower insulating layer 11 may possibly be etched. However, in a region sufficiently away from the gate electrode GE, no gate-drain leak occurs even if the lower insulating layer 11 is etched. Even if the lower insulating layer 11 is etched in this region, the oxide semiconductor layer 3 functions as an etch stop, and it is possible suppress the etch of the base insulating film.

The third portion D3 of the drain electrode DE may at least partially overlap with the gate electrode GE as seen from the direction normal to the substrate 1. In other words, as seen from the direction normal to the substrate 1, the first end portion e1 of the drain electrode DE on the gate electrode GE side may be located inside the gate electrode GE. By arranging the drain electrode DE so as to overlap with the gate electrode GE (or the gate bus line GL), it is possible to further improve the pixel aperture ratio while maintaining the size of the drain electrode DE. It is possible to more effectively prevent the lower insulating layer 11 from being etched and the gate electrode GE (or the gate bus line GL) from being exposed when patterning the upper insulating layer 13.

As shown in FIG. 2A, the stack contact portion 20A for electrically connecting together the pixel electrode PE and the oxide semiconductor layer 3 with the drain electrode DE interposed therebetween may be arranged in the pixel region Pix, and the source contact portion 21 for electrically connecting together the oxide semiconductor layer 3 and the source electrode SE may be arranged in another pixel region that is adjacent to the pixel region Pix in the column direction. In this case, the oxide semiconductor layer 3 may extend in an L-letter shape from the stack contact portion 20A to the source contact portion 21 while crossing the gate bus line GL.

The contact structure of the present embodiment is not limited to the example shown in FIGS. 2A to 2C. The present embodiment may be configured so that: (1) the contact portion between the pixel electrode PE and the oxide semiconductor layer 3 has a stack structure (that is, the drain opening 11d of the lower insulating layer 11 and the upper opening 13d of the upper insulating layer 13 at least partially overlap with each other as seen from the direction normal to the substrate 1); (2) the drain electrode DE is arranged on the lower insulating layer 11 and in the drain opening 11d and overlaps with only a portion of the drain opening 11d and only a portion of the upper opening 13d as seen from the direction normal to the substrate 1; and (3) the drain opening 11d and the upper opening 13d are located inside the oxide semiconductor layer 3 as seen from the direction normal to the substrate 1. With Such a structure, it is possible to reduce the size of the drain electrode DE to be smaller than those of conventional techniques, and it is therefore possible to improve the pixel aperture ratio and/or the definition. When patterning the upper insulating layer 13, the drain electrode DE and the oxide semiconductor layer 3 function as an etch stop, and it is therefore possible to suppress the overetch of the base insulating film, etc.

### Variations

Variations of the contact structure of the present embodiment will now be described with reference to the drawings. The following description will focus on differences from the structure shown in FIGS. 2A to 2C while omitting redundant description as appropriate.

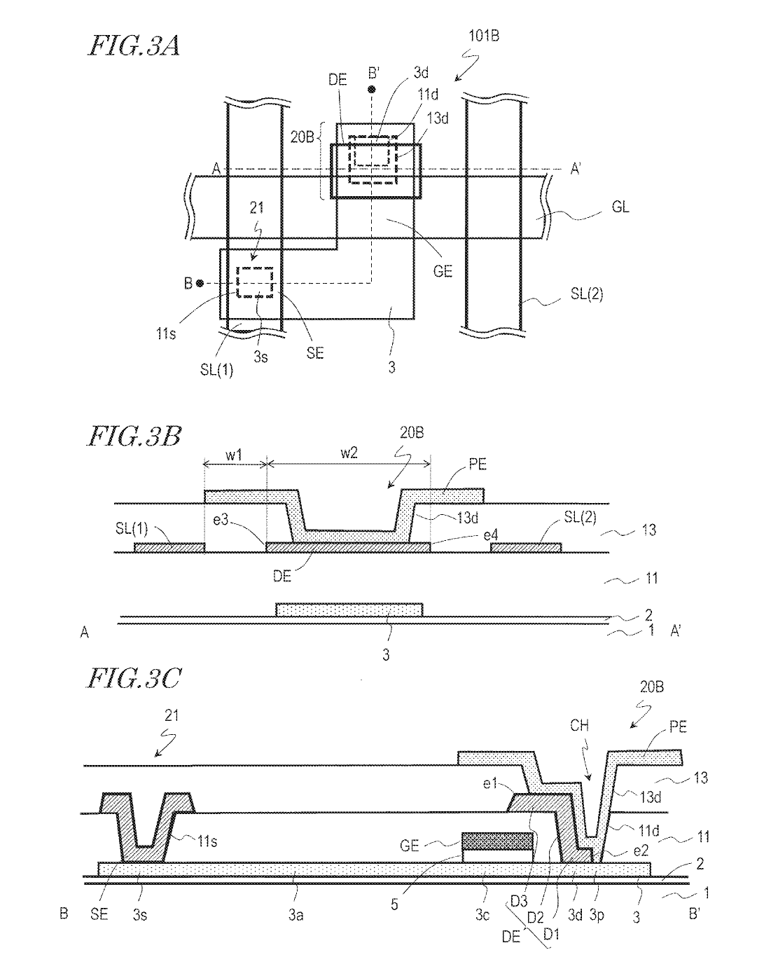

FIG. 3A is a plan view showing a TFT 101B and a stack contact portion 20B of Variation 1, and FIGS. 3B and 3C are cross-sectional views thereof taken along line A-A′ and line B-B′, respectively, of FIG. 3A.

Also in Variation 1, the third portion D3 of the drain electrode DE is arranged so as to at least partially overlap with the gate electrode GE (the gate bus line GL). Note however that in Variation 1, as shown in FIG. 3B, the width w2 of the drain electrode DE in the row direction is greater than the width of the upper opening 13d, and the third end portion e3 and the fourth end portion e4 of the drain electrode DE is located on the upper surface of the lower insulating layer 11 (i.e., the outer side of the upper opening 13d). Then, in the step of patterning the upper insulating layer 13, it is possible to more effectively prevent the lower insulating layer 11 from being etched to expose the gate bus line GL and the gate electrode GE.

Note that in this example, the width w2 of the drain electrode DE may be larger than the width of the oxide semiconductor layer 3 along the row direction and smaller than the width of the oxide semiconductor layer 3.

As shown in FIG. 3A, as seen from the direction normal to the substrate 1, the upper opening 13d may partially overlap with the gate electrode GE, and a portion of the upper opening 13d that overlaps with the gate electrode GE may be entirely located inside the drain electrode DE. Then, it is possible to more reliably suppress the leak due to the exposure of the gate electrode GE or the gate bus line GL, and to further improve the pixel aperture ratio.

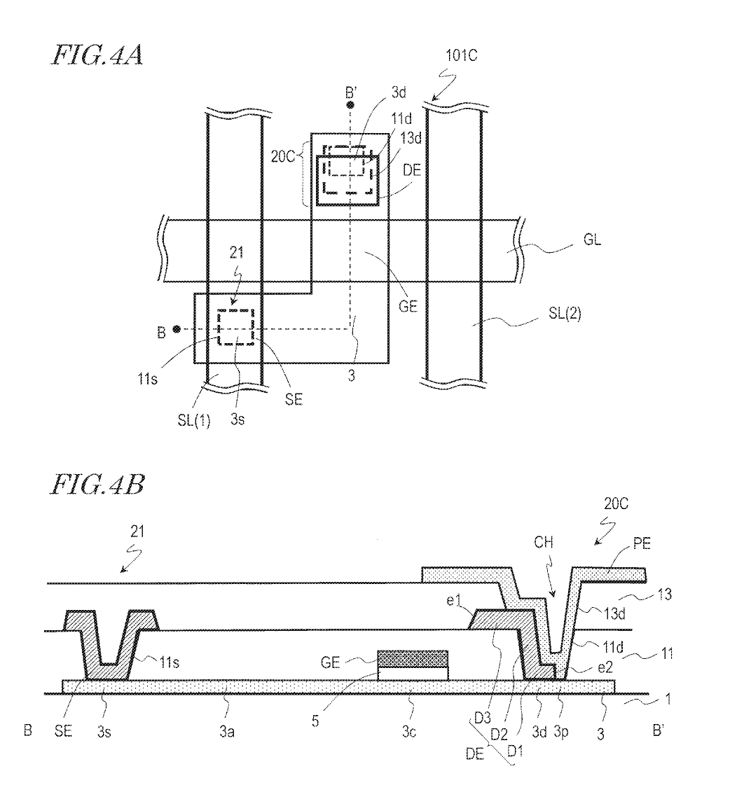

FIGS. 4A and 4B are a plan view showing a TFT 101C and a stack contact portion 20C of Variation 2 and a cross-sectional view taken along line B-B′, respectively.

As illustrated in Variation 2, the drain electrode DE does not need to overlap with the gate electrode GE as seen from the direction normal to the substrate 1. Then, it is possible to reduce the gate-drain capacitance. In this example, the width w2 of the drain electrode DE may be larger than the width of the upper opening 13d and smaller than the width of the upper opening 13d.

While the planar shape of the drain electrode DE is a rectangular shape having two sides extending in the row direction and two sides extending in the column direction in the examples shown in FIGS. 2A to 4B, there is no limitation on the planar shape of the drain electrode DE. As will be described below, the drain electrode DE may have a pattern such that the width of a portion the drain electrode DE that is located in the vicinity of the gate electrode GE or the gate bus line GL is larger than the width of other portions.

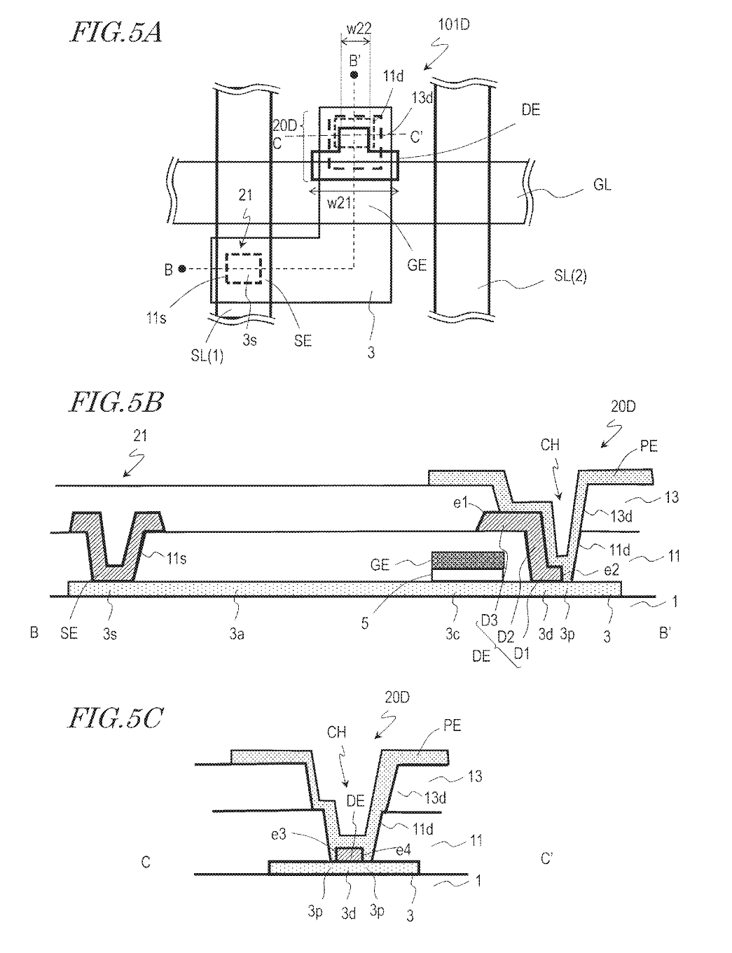

FIG. 5A is a plan view showing a TFT 101D and a stack contact portion 20D of Variation 3, and FIGS. 5B and 5C are cross-sectional views taken along line B-B′ and line C-C′, respectively.

In Variation 3, the drain electrode DE has an inverted T-letter shape as seen from the direction normal to the substrate 1. As seen from the direction normal to the substrate 1, the width w21 in the channel width direction (herein, the row direction) of the first end portion e1 of the drain electrode DE that is located on the gate electrode GE side is larger than the width w22 in the channel width direction (herein, the row direction) of the second end portion e2 that is located on the opposite side away from the gate electrode GE. By increasing the width w21 of the first end portion e1, it is possible to suppress the overetch of the lower insulating layer 11 by means of the drain electrode DE in the step of patterning the upper insulating layer 13, and it is therefore possible to suppress the leak due to the exposure of the gate electrode GE or the gate bus line GL. Moreover, by decreasing the width of the second end portion e2 of the drain electrode DE, it is possible to increase the pixel aperture ratio.

The proportion of the area of the transparent contact region 3p with respect to the area of the drain opening 11d as seen from the direction normal to the substrate 1 may be 50% or more and 80% or less. Then, it is possible to more effectively improve the pixel aperture ratio.

It is preferred that the width w21 of the first end portion e1 is larger than the width of the upper opening 13d. Then, it is possible to more reliably prevent the overetch of the lower insulating layer 11 in the step of patterning the upper insulating layer 13. The first end portion e1 may overlap with the gate electrode GE as seen from the direction normal to the substrate 1. As shown in the figure, as seen from the direction normal to the substrate 1, the upper opening 13d may partially overlap with the gate electrode GE, and a portion of the upper opening 13d that overlaps with the gate electrode GE may be entirely located inside the drain electrode DE. Then, it is possible to further improve the pixel aperture ratio while suppressing the leak due to the exposure of the gate electrode GE or the gate bus line GL.

The width w22 of the second end portion e2 may be set so that it is possible to ensure a contact area between the pixel electrode PE and the drain electrode DE, and it may be smaller than the width of the upper opening 13d. Alternatively, the width w22 of the second end portion e2 of the drain electrode DE may be 0.8 times or less the width w21 of the first end portion e1. Then, it is possible to more effectively increase the pixel aperture ratio. On the other hand, when the width w22 is 0.3 times or more the width w21, for example, it is possible to more reliably ensure a contact area.

As shown in FIG. 5C, on a cross section extending in the row direction through the drain electrode DE, the drain opening 11d and the upper opening 13d, the width w22 of the drain electrode DE may be smaller than the width of the upper opening 13d and the drain opening 11d in the row direction. In this case, on the bottom surface of the drain opening 11d, the transparent contact region 3p in contact with the pixel electrode PE may be arranged on the source bus line SL(1) side and/or the source bus line SL(2) side of the drain contact region 3d.

The planar shape of the drain electrode DE is not limited to an inverted T-letter shape as shown in FIG. 5A, but may be a triangular shape, a trapezoidal shape, etc. Note that even if the pattern of the resist mask used in the step of patterning the drain electrode DE is an inverted T-letter shape, a triangular shape, or the like, the patterned drain electrode DE may in some cases have a rounded trapezoidal shape.

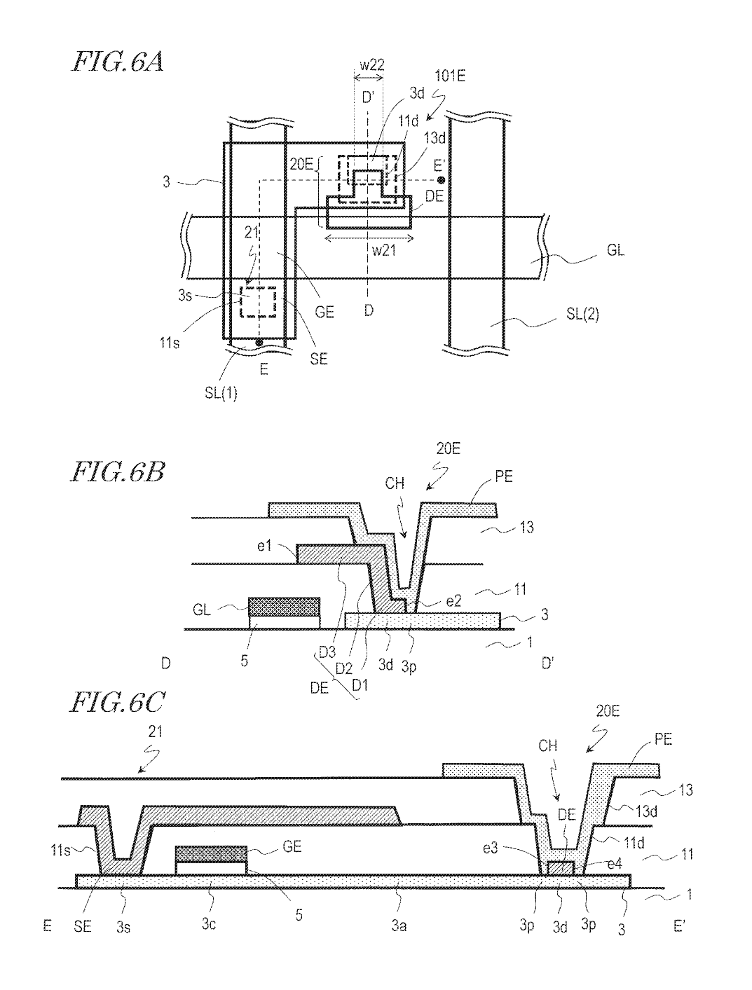

FIG. 6A is a plan view showing a TFT 101E and a stack contact portion 20E of Variation 4, and FIGS. 6B and 6C are cross-sectional views thereof taken along line D-D′ and line E-E′, respectively, of FIG. 6A.

Variation 4 is different from the TFT 101A shown in FIGS. 2A to 2C in that the oxide semiconductor layer 3 of the TFT 101E extends so as to partially overlap with the source bus line SL. In Variation 4, as seen from the direction normal to the substrate 1, the oxide semiconductor layer 3 extends, under the source bus line SL, from the source contact portion 21 to the intersection between the source bus line SL and the gate bus line GL. A portion of the gate bus line GL that is located at the intersection serves as the gate electrode GE. A portion of the oxide semiconductor layer 3 that is located closer to the drain than the gate electrode GE extends in parallel to the gate bus line GL (i.e., in the row direction) to the stack contact portion 20.

As seen from the direction normal to the substrate 1, the drain electrode DE is arranged spaced apart from the gate electrode GE (i.e., not overlapping with the gate electrode GE), and the third portion D3 of the drain electrode DE may at least partially overlap with a portion of the gate bus line GL that does not function as the gate electrode GE.

In this example, the drain electrode DE includes the first end portion e1 located on the gate bus line GL (excluding a portion that functions as the gate electrode GE) side, and the second end portion e2 located on the opposite side away from the gate bus line GL. The width of the drain electrode DE along the row direction is larger than that of the second end portion e2 of the first end portion e1 (the width w21 of the first end portion e1>the width w22 of the second end portion e2). As seen from the direction normal to the substrate 1, the first end portion e1 of the drain electrode DE may overlap with the gate bus line GL (excluding a portion that functions as the gate electrode GE). The relationship between the widths w21 and w22 of the drain electrode DE and the width of the upper opening 13d, etc., is similar to that of Variation 3 (FIGS. 5A to 5C), and the description thereof will be omitted.

Note that while the planar shape of the drain electrode DE is an inverted T-letter shape in FIG. 6A, it may be a rectangular shape (see FIGS. 2A to 2C, FIGS. 3A to 3C). The drain electrode DE does not need to overlap with the gate bus line GL.

While the oxide semiconductor layer 3 has an L-shaped pattern in any of the examples shown in FIGS. 2A to 6C, there is no particular limitation on the planar shape of the oxide semiconductor layer 3.

<Method for Manufacturing TFT 101 and Stack Contact Portion 20>

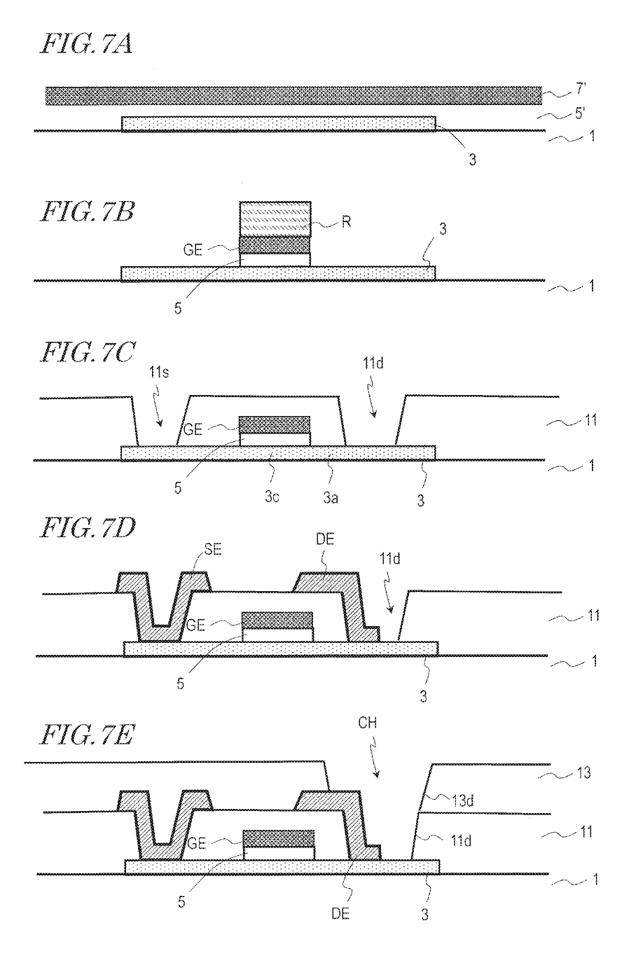

FIGS. 7A to 7E are step-by-step cross-sectional views illustrating an example of a method for manufacturing the TFT 101 pixel nd the stack contact portion 20.

First, as shown in FIG. 7A, the oxide semiconductor layer 3 is formed on the substrate 1. The substrate 1 may be a glass substrate, a silicon substrate, a plastic substrate (resin substrate) having a heat resistance, etc., for example. A lower insulating layer may be provided between the substrate 1 and the oxide semiconductor layer 3.

The oxide semiconductor layer 3 is formed as follows. First, an oxide semiconductor film (thickness: 15 nm or more and 200 nm or less, for example) is formed by a sputtering method, for example. The oxide semiconductor film may be an In—Ga—Zn—O-based semiconductor film, for example. Next, an annealing treatment of the oxide semiconductor film may be performed. Herein, a heat treatment at a temperature of 300° C. or more and 500° C. or less is performed in the atmosphere for 30 minutes or more and 2 hours or less, for example. Next, the oxide semiconductor film is patterned by wet etching, for example, thereby obtaining the oxide semiconductor layer 3.

Next, as shown in FIG. 7B, an insulating film (thickness: 90 nm or more and 200 nm or less) 5′ to be the gate insulating film and a conductive film (thickness: 60 nm or more and 700 nm or less) 7′ to be the gate electrode are deposited in this order so as to cover the oxide semiconductor layer 3.

The insulating layer 5′ is a silicon oxide (SiOx) layer, for example. A metal such as molybdenum (Mo), tungsten (W), aluminum (Al), copper (Cu), titanium (Ti), tantalum (Ta), etc., or an alloy thereof may be used as the conductive film 7′, for example. The conductive film 7′ may have a layered structure including a plurality of layers formed from different conductive materials.

Next, as shown in FIG. 7B, a gate metal layer including the gate electrode GE and the gate bus line (not shown) is formed by patterning the conductive film 7′. Specifically, first, a resist layer R to be the etching mask is formed on a portion of the conductive film 7′ through a photolithography step. Next, the conductive film 7′ is patterned by wet etching using the resist layer R as a mask, thereby obtaining the gate electrode GE.

Then, the insulating layer 5′ is patterned by dry etching using the resist layer R as a mask, thereby obtaining the gate insulating layer 5. The oxide semiconductor layer 3 is exposed excluding a portion thereof that overlaps with the gate electrode GE. The surface layer of the exposed oxide semiconductor layer 3 may be overetched in some cases. Then, the resist layer R is removed. Note that for the purpose of protecting the oxide semiconductor layer 3 from a resist remover solution, the insulating layer 5′ may be patterned using the gate electrode GE as a mask after the removal of the resist layer R.

Next, as shown in FIG. 7C, the lower insulating layer 11 is formed so as to cover the oxide semiconductor layer 3, the gate insulating layer 5 and the gate electrode GE. The lower insulating layer 11 is a silicon oxide (SiOx) layer, a silicon nitride (SiNx) layer or a silicon oxide nitride (SiNxOy) layer, for example. The lower insulating layer 11 may have a layered structure including these layers layered on each other. The thickness of the lower insulating layer 11 is 150 nm or more and 500 nm or less, for example.

The lower insulating layer 11 may include a hydrogen-donating layer such as a silicon nitride layer, for example. By arranging the silicon nitride layer so as to be in contact with the oxide semiconductor layer 3, a portion of the oxide semiconductor layer 3 that is in contact with the silicon nitride layer is reduced to be the low-resistance region 3a that has a lower electrical resistivity than a portion (the channel region 3c) in contact with the gate insulating layer 5.

Then, the source opening 11s and the drain opening 11d are formed in the lower insulating layer 11 so that a portion of the oxide semiconductor layer 3 is exposed. The etching method may be dry etching or wet etching.

Then, a source-drain conductive film (not shown) is formed by a sputtering method, for example, on the lower insulating layer 11 and in the source opening 11s and the drain opening 11d, and the conductive film is patterned. Then, as shown in FIG. 7D, a source metal layer including the source electrode SE, the drain electrode DE and the source bus line (not shown) is formed. The thickness of the source electrode SE and the drain electrode DE is 100 nm or more and 500 nm or less, for example.

In the present embodiment, the source electrode SE is arranged so as to cover the entire source opening 11s, and is in contact with the oxide semiconductor layer 3 in the source opening 11s. The drain electrode DE is arranged so as to cover only a portion of the drain opening 11d, and is in contact with the oxide semiconductor layer 3 in the drain opening 11d. Thus, the TFT 101 is manufactured.

The material of the source-drain conductive film may be a metal such as molybdenum (Mo), tungsten (W), aluminum (Al), copper (Cu), titanium (Ti), tantalum (Ta), etc., or an alloy thereof. The source-drain conductive film may be a layered film including three layers of a Ti film (thickness: 30 nm), an Al film (thickness: 300 nm) and a Ti film (thickness: 50 nm), or two layers of a Ti film (thickness: 30 nm) and a Cu film (thickness: 300 nm), stacked in this order starting from the side of the oxide semiconductor layer 3.

Then, as shown in FIG. 7E, the upper insulating layer 13 is formed so as to cover the source metal layer. Next, the upper insulating layer 13 is etched, thereby forming the upper opening 13d. The upper insulating layer 13 may be etched by using wet etching or dry etching. In this process, the etching conditions are selected according to the materials of the various layers so that the upper insulating layer 13 is etched and the oxide semiconductor layer 3 and the drain electrode DE are not etched. The etching conditions as used herein include, where dry etching is used, the type of the etching gas, the temperature of the substrate 1, the degree of vacuum in the chamber, etc. Where wet etching is used, they include the type of the etchant, the etching time, etc.

The upper opening 13d is arranged so as to at least partially overlap with the drain opening 11d. As seen from the direction normal to the substrate 1, the size of the upper opening 13d may be larger than the drain opening 11d, and the drain opening 11d may be located inside the upper opening 13d.

When etching the upper insulating layer 13, the lower insulating layer 11 may also be etched, thereby increasing the size of the drain opening 11d from the size of the drain opening 11d as formed. In this case, as shown in the figure, a portion of the side surface of the upper opening 13d and a portion of the side surface of the drain opening 11d may be aligned with each other. Note that even if the lower insulating layer 11 is etched, the oxide semiconductor layer 3 functions as an etch stop and therefore the insulating film on the substrate 1 side of the oxide semiconductor layer 3 is not etched.

When the thickness of the upper insulating layer 13 is 50 nm or more, for example, it is possible to more reliably ensure electric insulation between the source metal layer and the gate metal layer. On the other hand, when the thickness of the upper insulating layer 13 is 800 nm or less, for example, it is possible to suppress the decrease in the display contrast due to light scattering that occurs in a region of the side surface of the upper opening 13d that is not shaded by the drain electrode DE.

The upper insulating layer 13 may be an inorganic insulating layer or an organic insulating layer. In order to reduce the thickness of the upper insulating layer 13, it is preferred that the upper insulating layer 13 is an inorganic insulating layer such as a silicon oxide (SiO₂) layer, a silicon nitride (SiNx) layer or a silicon oxide nitride (SiOxNy) layer.

Next, although not shown in the figures, a transparent conductive film is formed on the upper insulating layer 13 and in the upper opening 13d and the transparent conductive film is patterned, thereby obtaining the pixel electrode PE. The pixel electrode PE is in direct contact with the drain electrode DE and the oxide semiconductor layer 3 in the contact hole CH.

For example, an ITO (indium-tin oxide) film, an In—Zn—O-based oxide (indium-zinc oxide) film, a ZnO film (zinc oxide film), etc., may be used as the transparent conductive film. Thus, the active matrix substrate 1000 is manufactured.

<Regarding Oxide Semiconductor>

The oxide semiconductor included in the oxide semiconductor layer 3 may be an amorphous oxide semiconductor or a crystalline oxide semiconductor including a crystalline portion. Examples of the crystalline oxide semiconductor include a polycrystalline oxide semiconductor, a microcrystalline oxide semiconductor, and a crystalline oxide semiconductor whose c-axis is oriented generally perpendicular to the layer surface.

The oxide semiconductor layer 3 may have a layered structure of two layers or more. When the oxide semiconductor layer 3 has a layered structure, the oxide semiconductor layer 3 may include an amorphous oxide semiconductor layer and a crystalline oxide semiconductor layer. Alternatively, it may include a plurality of crystalline oxide semiconductor layers of different crystalline structures. It may include a plurality of amorphous oxide semiconductor layers. When the oxide semiconductor layer 3 has a two-layer structure including an upper layer and a lower layer, the energy gap of the oxide semiconductor included in the upper layer preferably has a greater energy gap than that of the oxide semiconductor included in the lower layer. Note however that when the difference in energy gap between these layers is relatively small, the energy gap of the oxide semiconductor of the lower layer may be greater than the energy gap of the oxide semiconductor of the upper layer.

The material, the structure, the film formation method of the amorphous oxide semiconductor and each of the crystalline oxide semiconductors, and the configuration of an oxide semiconductor layer having a layered structure, etc., are described in Japanese Laid-Open Patent Publication No. 2014-007399, for example. The disclosure of Japanese Laid-Open Patent Publication No. 2014-007399 is herein incorporated by reference in its entirety.

The oxide semiconductor layer 3 may include at least one metal element from among In, Ga and Zn, for example. In the present embodiment, the oxide semiconductor layer 3 includes an In—Ga—Zn—O-based semiconductor (e.g., indium gallium zinc oxide), for example. Herein, an In—Ga—Zn—O-based semiconductor is a ternary oxide of In (indium), Ga (gallium) and Zn (zinc), and there is no particular limitation on the ratio (composition ratio) between In, Ga and Zn, examples of which include In:Ga:Zn=2:2:1, In:Ga:Zn=1:1:1 and In:Ga:Zn=1:1:2, for example. Such an oxide semiconductor layer 3 can be formed from an oxide semiconductor film including an In—Ga—Zn—O-based semiconductor.

An In—Ga—Zn—O-based semiconductor may be amorphous or crystalline. A crystalline In—Ga—Zn—O-based semiconductor is preferably a crystalline In—Ga—Zn—O-based semiconductor whose c-axis is oriented generally perpendicular to the layer surface.

Note that crystalline structures of crystalline In—Ga—Zn—O-based semiconductors are disclosed in, for example, Japanese Laid-Open Patent Publication No. 2014-007399, supra, Japanese Laid-Open Patent Publication No. 2012-134475, Japanese Laid-Open Patent Publication No. 2014-209727, etc. The disclosures of Japanese Laid-Open Patent Publication No. 2012-134475 and Japanese Laid-Open Patent Publication No. 2014-209727 are herein incorporated by reference in their entirety. Since TFTs including an In—Ga—Zn—O-based semiconductor layer have a high mobility (more than 20 times that of an a-SiTFT) and a low leak current (less than 1/100 that of an a-SiTFT), they can desirably be used as driver TFTs (e.g., TFTs included in driver circuits provided around the display region including a plurality of pixels and on the same substrate as the display region) and pixel TFTs (TFTs provided in pixels).

The oxide semiconductor layer 3 may include another oxide semiconductor, instead of an In—Ga—Zn—O-based semiconductor. For example, it may include an In—Sn—Zn—O-based semiconductor (e.g., In₂O₃—SnO₂—ZnO; InSnZnO). An In—Sn—Zn—O-based semiconductor is a ternary oxide of In (indium), Sn (tin) and Zn (zinc). Alternatively, the oxide semiconductor layer 3 may include an In—Al—Zn—O-based semiconductor, an In—Al—Sn—Zn—O-based semiconductor, a Zn—O-based semiconductor, an In—Zn—O-based semiconductor, a Zn—Ti—O-based semiconductor, a Cd—Ge—O-based semiconductor, a Cd—Pb—O-based semiconductor, a CdO (cadmium oxide), an Mg—Zn—O-based semiconductor, an In—Ga—Sn—O-based semiconductor, an In—Ga—O-based semiconductor, a Zr—In—Zn—O-based semiconductor, an Hf—In—Zn—O-based semiconductor, an Al—Ga—Zn—O-based semiconductor, a Ga—Zn—O-based semiconductor, an In—Ga—Zn—Sn—O-based semiconductor, etc.

### Second Embodiment

An active matrix substrate of a second embodiment is different from the first embodiment in that polysilicon TFTs having a top gate structure are used as pixel TFTs.

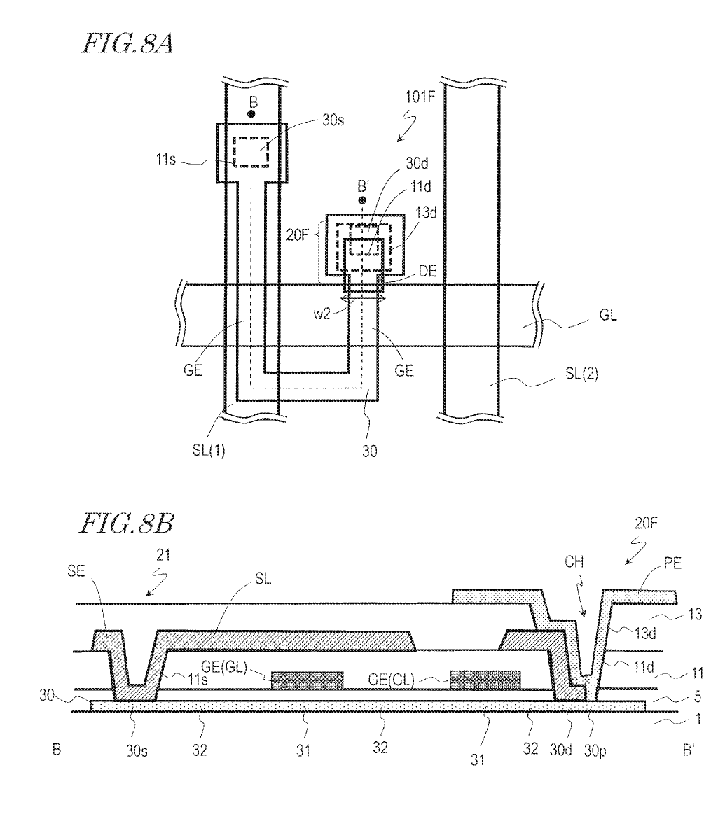

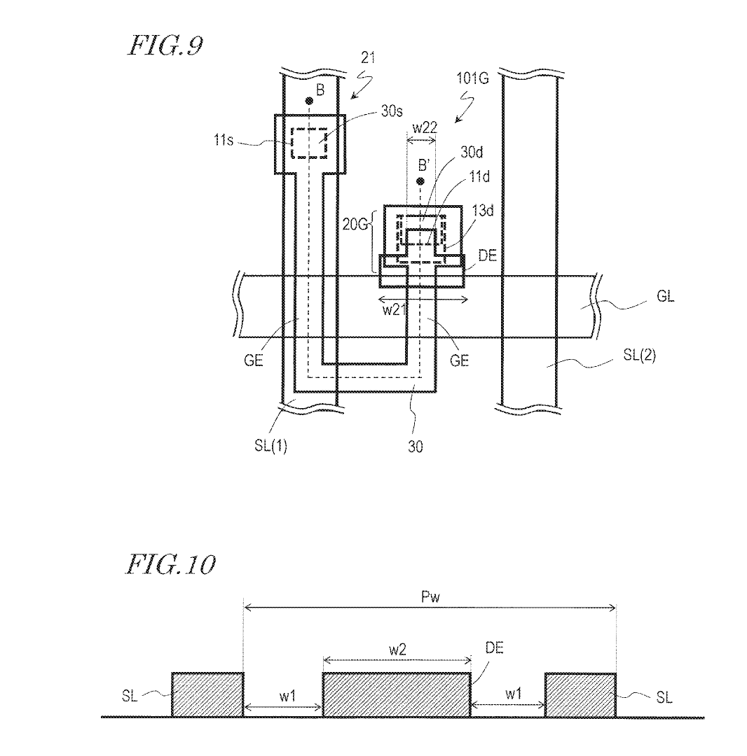

FIGS. 8A and 8B are a plan view and a cross-sectional view, respectively, showing a TFT 101F and a stack contact portion 20F of the present embodiment. The following description will focus on differences from the embodiment described above while omitting redundant description as appropriate.

The TFT 101F includes a crystalline silicon semiconductor layer 30 as the active layer. The crystalline silicon semiconductor layer 30 is covered by the gate insulating layer 5, and the gate electrode GE is arranged on the gate insulating layer 5 so as to overlap with a portion of the crystalline silicon semiconductor layer 30. The gate insulating layer 5 may cover not only portions below the gate electrodes GE but also the entire crystalline silicon semiconductor layer 30 (excluding a source contact region 30s and a drain contact region 30d to be described below).

The crystalline silicon semiconductor layer 30 includes one or more channel regions 31 that overlap with the gate electrodes GE with the gate insulating layer 5 interposed therebetween, and a high-concentration impurity region 32 that is arranged in portions other than the channel region 31 and that has an impurity at a higher concentration than the channel region 31. The high-concentration impurity region 32 has an electrical resistivity lower than the channel region 31.

The gate insulating layer 5 and the gate electrode GE are covered by the lower insulating layer 11. The source electrode SE is arranged on the lower insulating layer 11 and in the source opening 11s, which is provided in the lower insulating layer 11 and the gate insulating layer 5, and is in contact with a portion of the high-concentration impurity region 32 in the source opening 11s. The drain electrode DE is arranged on the lower insulating layer 11 and in the drain opening 11d, which is provided in the lower insulating layer 11 and the gate insulating layer 5, and is in contact with a portion of the high-concentration impurity region 32 in the drain opening 11d. Also in the present embodiment, the drain electrode DE is in contact with only a portion of the exposed portion of the crystalline silicon semiconductor layer 30 that is exposed through the drain opening 11d.

The upper insulating layer 13 is provided on the lower insulating layer 11 and the source metal layer (the source electrode SE, the drain electrode DE and the source bus line SL). The upper opening 13d is provided in the upper insulating layer 13 so as to partially overlap with the drain opening 11d (the stack structure). As seen from the direction normal to the substrate 1, the drain opening 11d and the upper opening 13d are located inside the crystalline silicon semiconductor layer 30. The pixel electrode PE is arranged on the upper insulating layer 13, and is in direct contact with the drain electrode DE and the crystalline silicon semiconductor layer 30 in the contact hole CH, which is formed by the upper opening 13d and the drain opening 11d. A portion of the crystalline silicon semiconductor layer 30 that is in contact with the drain electrode DE and the source electrode SE is referred to as the drain contact region 30d, and a portion thereof that is in contact with the source contact region 30s and the pixel electrode PE as a transparent contact region 30p.

Also in the present embodiment, the crystalline silicon semiconductor layer 30 can be made to function as an etch stop when patterning the upper insulating layer 13, and it is therefore possible to arrange the drain electrode DE so as to overlap with only a portion of the drain opening 11d and only a portion of the upper opening 13d. Therefore, the size of the drain electrode DE can be made smaller than those of conventional techniques, and it is possible to improve the pixel aperture ratio. By setting the width w2 of the drain electrode DE in the row direction to be smaller than the width of the upper opening 13d, it is possible to reduce the pixel width Pw and realize a higher definition.

It is preferred that the TFT 101F has a structure in which two TFTs are connected in series (referred to as the “dual gate structure”). With the dual gate structure, a plurality of (herein, two) gate electrodes GE are arranged with an interval therebetween on one crystalline silicon semiconductor layer 30. That is, a plurality of (herein, two) channel regions 31 are formed between the source contact region 30s and the drain contact region 30d of the crystalline silicon semiconductor layer 30. The high-concentration impurity region 32 is arranged between two adjacent channel regions 31.

The TFT 101F preferably has the dual gate structure for the following reason. Pixel TFTs used in an active matrix substrate of a liquid crystal display device are required to have a small off-leak current. This is for the following reason. While a liquid crystal display device needs to hold the voltage applied through the liquid crystal material over a period of one frame until the screen is rewritten, if the off-leak current of the pixel TFTs is large, the voltage applied to the liquid crystal material may possibly decrease over time, thereby deteriorating the display characteristics. A polysilicon TFT has poorer off-leak characteristics than an oxide semiconductor TFT or an amorphous silicon TFT, and if a similar TFT structure (FIGS. 2A to 6C) to that of an oxide semiconductor TFT is used for a polysilicon TFT, the off-leak current may become large and desired display characteristics may not be realized in some cases. In contrast, if a dual gate structure as shown in FIGS. 8A and 8B is used, it is possible to reduce the voltage between the source electrode SE and the drain electrode DE to about ½, and it is possible to keep the off-leak current small.

In this example, the crystalline silicon semiconductor layer 30 extends in a U-letter shape from the source contact portion 21 to the stack contact portion 20F while twice crossing the gate bus line GL. The two portions of the gate bus line GL that are crossed by the crystalline silicon semiconductor layer 30 function as gate electrodes GE. With this configuration, it is possible to reduce the pixel width Pw as compared with a case where the gate electrode GE is provided separately, and it is possible to improve the pixel aperture ratio.

Next, with reference to FIGS. 8A and 8B, an example of a method for manufacturing the TFT 101F and the stack contact portion 20F will be described.

First, a base film (not shown) is formed on the substrate 1, and an amorphous silicon (a-Si) film is formed thereon by a method known in the art, such as a plasma CVD (Chemical Vapor Deposition) method or a sputtering method, for example. Next, a crystalline silicon (p-Si) film is obtained by crystallizing a-Si. The crystallization of an a-Si film may be performed by irradiating the a-Si film with excimer laser light, for example. Then, the p-Si film is patterned to form a semiconductor layer (thickness: 30 nm or more and 70 nm or less, for example) 30 made of crystalline silicon. The gate insulating layer 5 is formed so as to cover the crystalline silicon semiconductor layer 30. The gate insulating layer 5 is an SiNx layer, for example.

Then, a gate conductive film is formed on the gate insulating layer 5 and patterned, thereby obtaining the gate electrode GE. In this step, the gate insulating layer 5 does not need to be patterned.

Then, an impurity is injected into the crystalline silicon semiconductor layer 30 using the gate electrode GE as a mask, thereby forming the high-concentration impurity region 32. A region of the crystalline silicon semiconductor layer 30 where an impurity is not injected serves as the channel region 3c.

Then, the lower insulating layer 11, the source electrode SE and the drain electrode DE, the upper insulating layer 13 and the pixel electrode PE are formed as in the embodiment described above. Thus, an active matrix substrate is manufactured.

Note that the structure of the pixel TFT and the stack contact portion of the present embodiment is not limited to the example shown in FIGS. 8A and 8B. For example, the drain electrode DE may have a planar shape other than a rectangular shape, such as an inverted T-letter shape, as shown in FIG. 9. The widths w21 and w22, the arrangement, etc., of the drain electrode DE may be similar to those described above with reference to FIGS. 5A to 5C. There is no particular limitation on the positional relationship between the drain electrode DE and the upper opening 13d and the drain opening 11d, and similar variations to those of the first embodiment are possible.

An active matrix substrate according to an embodiment of the present invention is suitably applicable to liquid crystal display devices for use in smart phones, head-mounted displays, etc. The application is not limited to liquid crystal display devices, but may suitably include various display devices such as organic EL display devices.

This application is based on Japanese Patent Application No. 2018-056104 filed on Mar. 23, 2018, the entire contents of which are hereby incorporated by reference.

What is claimed is:

1. An active matrix substrate having a plurality of pixel regions, each pixel region including a thin film transistor supported on a substrate and a pixel electrode, wherein:
the thin film transistor includes:
a semiconductor layer supported on the substrate;
a gate electrode arranged on the semiconductor layer with a gate insulating layer interposed therebetween;
a lower insulating layer covering the gate electrode and the semiconductor layer, the lower insulating layer having a source opening and a drain opening through which a portion of the semiconductor layer is exposed; and
a source electrode arranged on the lower insulating layer to be in contact with the semiconductor layer in the source opening, and a drain electrode arranged on the lower insulating layer to be in contact with the semiconductor layer in the drain opening;
the drain electrode includes a first portion in contact with only a portion of an exposed portion of the semiconductor layer that is exposed through the drain opening, a second portion located on a side surface of the drain opening, and a third portion located on an upper surface of the lower insulating layer;
the active matrix substrate further comprises an upper insulating layer covering the thin film transistor, wherein the upper insulating layer has an upper opening that at least partially overlaps with the drain opening, and the upper opening and the drain opening together form a contact hole running through the upper insulating layer and the lower insulating layer;
as seen from a direction normal to the substrate, the upper opening and the drain opening are located inside the semiconductor layer;
as seen from a direction normal to the substrate, the drain electrode overlaps with only a portion of the drain opening and only a portion of the upper opening; and
in the contact hole, the pixel electrode is in direct contact with at least the first portion and the second portion of the drain electrode and another portion of the exposed portion of the semiconductor layer.

2. The active matrix substrate according to claim 1, wherein as seen from a direction normal to the substrate, the third portion of the drain electrode is located on a side of the gate electrode relative to the first portion.

3. The active matrix substrate according to claim 1, wherein as seen from a direction normal to the substrate, the third portion of the drain electrode at least partially overlaps with the gate electrode.

4. The active matrix substrate according to claim 1, wherein as seen from a direction normal to the substrate, a width of the drain electrode along a channel width direction of the thin film transistor is smaller than a width of the upper opening along the channel width direction.

5. The active matrix substrate according to claim 4, wherein on a cross section perpendicular to the substrate and extending through the drain electrode and the upper opening in the channel width direction, the drain electrode is located inside the upper opening.

6. The active matrix substrate according to claim 1, wherein:
as seen from a direction normal to the substrate, the drain electrode includes a first end portion located on a side of the gate electrode and a second end portion located on an opposite side away from the gate electrode; and
a first width of the first end of the drain electrode along a channel width direction of the thin film transistor is larger than a second width of the second end portion of the drain electrode along the channel width direction.

7. The active matrix substrate according to claim 6, wherein as seen from a direction normal to the substrate, the first width is larger than a width of the upper opening along the channel width direction, and the second width is smaller than the width of the upper opening along the channel width direction.

8. The active matrix substrate according to claim 6, wherein:
as seen from a direction normal to the substrate, the upper opening and the gate electrode at least partially overlap with each other; and
as seen from a direction normal to the substrate, a portion of the upper opening that overlaps with the gate electrode is entirely located inside the drain electrode.

9. The active matrix substrate according to claim 1, wherein:
the active matrix substrate includes a plurality of source bus lines extending in a column direction, and a plurality of gate bus lines extending in a row direction crossing the column direction;
the source electrode is connected to a corresponding one of the plurality of source bus lines, and the gate electrode is connected to a corresponding one of the plurality of gate bus lines; and
the source electrode and the drain electrode are formed from the same conductive film as the plurality of source bus lines.

10. The active matrix substrate according to claim 1, wherein:
the active matrix substrate includes a plurality of source bus lines extending in a column direction, and a plurality of gate bus lines extending in a row direction crossing the column direction;
the source electrode is connected to a corresponding one of the plurality of source bus lines, and the gate electrode is connected to a corresponding one of the plurality of gate bus lines;
the source electrode and the drain electrode are formed from the same conductive film as the plurality of source bus lines;
as seen from a direction normal to the substrate, a portion of the semiconductor layer that is located closer to the drain electrode than the gate electrode extends in the row direction;
the drain electrode includes a first end portion located on a side of the corresponding gate bus line, and a second end portion located on an opposite side away from the corresponding gate bus line; and
a first width of the first end of the drain electrode along the row direction is larger than a second width of the second end portion of the drain electrode along the row direction.

11. The active matrix substrate according to claim 10, wherein as seen from a direction normal to the substrate, the first width is larger than a width of the upper opening along the row direction, and the second width is smaller than the width of the upper opening along the row direction.

12. The active matrix substrate according to claim 1, wherein:
the active matrix substrate includes a plurality of source bus lines extending in a column direction, and a plurality of gate bus lines extending in a row direction crossing the column direction;
the source electrode is connected to a corresponding one of the plurality of source bus lines, and the gate electrode is connected to a corresponding one of the plurality of gate bus lines;
the source electrode and the drain electrode are formed from the same conductive film as the plurality of source bus lines;
as seen from a direction normal to the substrate, a portion of the semiconductor layer that is located closer to the drain electrode than the gate electrode extends in the row direction; and
as seen from a direction normal to the substrate, the drain electrode is arranged spaced apart from the gate electrode, and the third portion of the drain electrode at least partially overlaps with the corresponding gate bus line.

13. The active matrix substrate according to claim 9, wherein:
the source opening is arranged so as to overlap with the corresponding source bus line; and
as seen from a direction normal to the substrate, the semiconductor layer extends in an L-letter shape from the source opening to the contact hole while crossing the corresponding gate bus line.

14. The active matrix substrate according to claim 9, wherein:
the source opening is arranged so as to overlap with the corresponding source bus line; and
as seen from a direction normal to the substrate, the semiconductor layer extends in a U-letter shape from the source opening to the contact hole while twice crossing the corresponding gate bus line.

15. The active matrix substrate according to claim 1, wherein the semiconductor layer is an oxide semiconductor layer.

16. The active matrix substrate according to claim 15, wherein the oxide semiconductor layer includes an In—Ga—Zn—O-based semiconductor.

17. The active matrix substrate according to claim 16, wherein the oxide semiconductor layer includes a crystalline portion.

18. The active matrix substrate according to claim 14, wherein the semiconductor layer is a crystalline silicon semiconductor layer.

19. A method for manufacturing an active matrix substrate, comprising the steps of:
forming a semiconductor layer on a substrate;
forming a gate electrode on a portion of the semiconductor layer with a gate insulating layer interposed therebetween;
forming a lower insulating layer so as to cover the semiconductor layer and the gate electrode, and forming a drain opening in the lower insulating layer, through which a portion of the semiconductor layer is exposed;
forming a drain electrode on the lower insulating layer and in the drain opening, wherein the drain electrode is in contact with only an exposed portion of the semiconductor layer in the drain opening;
forming an upper insulating layer so as to cover the lower insulating layer and the drain electrode;
patterning the upper insulating layer so as to form an upper opening that at least partially overlaps with the drain opening, wherein the drain electrode and the semiconductor layer are made to function as an etch stop during the patterning; and
forming a pixel electrode on the upper insulating layer, in the upper opening and in the drain opening.
